(19) United States
(12) Patent Application Publication
(10) Pub. No.: US 2012/0181499 A1
(43) Pub. Date: Jul. 19, 2012

(54) QUATERNARY GALLIUM TELLURIUM ANTIMONY (M-GaTeSb) BASED PHASE CHANGE MEMORY DEVICES

(75) Inventors: Tung-Hua Chuang, Taipei (TW); Yi-Chou Chen, Hsinchu (TW); Tsung-Shune Chin, Hsinchu (TW); Kin-Fu Kao, Taipei (TW); Po-Chin Chang, Taichung (TW); Yung-Ching Chu, Hsinchu (TW)

(73) Assignee: Macronix International Co., Ltd., Hsinchu (TW)

(21) Appl. No.: 13/046,994

(22) Filed: Mar. 14, 2011

Related U.S. Application Data
(60) Provisional application No. 61/434,331, filed on Jan. 19, 2011.

(51) Int. Cl. H01L 45/00; C09K 3/00

(52) U.S. Cl. 257/2; 252/182.33; 257/E45.001

(57) ABSTRACT

A phase change material comprising a quaternary GaTeSb material consisting essentially of M_{A}(GaₓTe_{y}Sb_{z})_{B}, and where M comprises a group IVA element C, Si, Ge, Sn, Pb, a group VA element N, P, As, Sb, Bi, or a group VIA element O, S, Se, Te, Po, having a value A such that the transition temperature is increased relative to the transition temperature in GaₓTe_{y}Sb_{z}, without M, and the difference between the melting temperature and the transition temperature is reduced relative to the difference in GaₓTe_{y}Sb_{z}, without M.

### RELATED APPLICATIONS

This application claims the benefit of U.S. Provisional Patent Application No. 61/434,331 filed on 19 Jan. 2011, and said application is incorporated by reference as if fully set forth herein.

### BACKGROUND OF THE INVENTION

1. Field of the Invention

The present invention relates to phase change memory devices, and materials utilized in such devices.

2. Description of Related Art

Phase change based memory materials, like chalcogenide based materials and similar materials, can be caused to change phase between an amorphous and a crystalline state by application of electrical current at levels suitable for implementation in integrated circuits. The generally amorphous state is characterized by higher electrical resistivity than the generally crystalline state, which can be readily sensed to indicate data. These properties have generated interest in using phase change material to form nonvolatile memory circuits, which can be read and written with random access.

There has been significant development of phase change materials for use in integrated circuits based on the chalcogenide, of Ge₂Sb₂Te₅, known as GST. Other chalcogenides may be used as well. Chalcogens include any of the four elements oxygen (O), sulfur (S), selenium (Se), and Tellurium (Te), forming part of group VIA of the periodic table. Chalcogenides comprise compounds of a chalcogen with a more electropositive element or radical. Chalcogenide alloys comprise combinations of chalcogenides with other materials such as transition metals. A chalcogenide alloy usually contains one or more elements from group IVA of the periodic table of elements, such as germanium (Ge) and tin (Sn). Often, chalcogenide alloys include combinations including one or more of antimony (Sb), gallium (Ga), indium (In), and silver (Ag). Many phase change based memory materials have been described in technical literature, including alloys of: Ga/Sb, In/Sb, In/Se, Sb/Te, Ge/Te, Ge/Sb/Te, In/Sb/Te, Ga/Se/Te, Sn/Sb/Te, In/Sb/Ge, Ag/In/Sb/Te, Ge/Sn/Sb/Te, Ge/Sb/Se/Te and Te/Ge/Sb/S. In the family of Ge/Sb/Te alloys, a wide range of alloy compositions may be workable.

Phase change materials base on alloys of gallium, tellurium and antimony (GaTeSb) have also been described. See, Chin et al., US 2009/0194759 and Liang et al, US 2009/0230375 (see paragraph [0035]).

Performance of phase change memory devices is often characterized in terms of switching speed, switching current, data retention and endurance. Of course, optimizing these characteristics involves tradeoffs in design that make identification of workable materials very difficult.

It is desirable to provide memory devices that operate with high speed and low power, with good data retention and endurance, and memory materials which can be used in manufacturing such devices.

### SUMMARY OF THE INVENTION

A memory device is described herein including a phase change material that comprises a fourth element, such as silicon, incorporated into a GaTeSb system (M-GaTeSb) to produce a quaternary phase change material with higher crystallization temperature, higher crystallization resistance, and lower melting point. The quaternary GaTeSb system (M-GaTeSb) described herein is further characterized by being a growth dominated crystallization system.

It has been discovered that phase change material of the class M-GaTeSb can be formulated to increase the crystallization threshold temperature without increasing the melting temperature (and thereby resulting in a reduced difference between the melting and transition temperatures). In this way, better data retention is achieved without increasing the power needed to accomplish a reset operation, and without increasing the switching time.

A phase change material having a melting temperature and a crystallization transition temperature, and a difference between the melting temperature and transition temperature, comprising M_{A}(GaₓTe_{y}Sb_{z})_{B}, where x, y and z are variables, where M comprises an element select from C, Si, Ge, Sn, Pb, N, P, As, Sb, Bi, O, S, Se, Te, and Po, and wherein A and B are positive, non-zero numbers, having a value A such that the transition temperature is increased relative to the transition temperature in GaₓTe_{y}Sb_{z}, without M, and the difference between the melting temperature and the transition temperature is reduced relative to the difference in GaₓTe_{y}Sb_{z}, without M, and further characterized by being a growth dominated crystallization system. Preferably the parameters (x, y, z) satisfy at least on of the relations (z>x, z>y) and (z≧x+y).

By using a phase change material comprising a quaternary GaTeSb system with high crystallization temperature, the retention property can be improved.

By using a phase change material comprising a quaternary GaTeSb system with high resistance, the switching time can be reduced.

By using a phase change material comprising a quaternary GaTeSb system with high resistance, the switching current can be reduced.

By using a phase change material comprising a quaternary GaTeSb system comprising a quaternary GaTeSb system with low melting temperature, the switching current can be reduced.

By using a phase change material comprising a quaternary GaTeSb system with low melting temperature, the switching time can be reduced.

Other aspects and advantages of the present invention can be seen on review of the drawings, the detailed description and the claims, which follow.

### BRIEF DESCRIPTION OF THE DRAWINGS

FIG. 1 is a simplified diagram of a memory cell having a quaternary M-GaTeSb phase change material.

FIG. 2 is a simplified diagram of an alternative memory cell having a quaternary memory cell having a quaternary M-GaTeSb phase change material.

FIG. 3 is a simplified diagram of another alternative memory cell having a quaternary M-GaTeSb phase change material.

FIG. 4 is a simplified diagram of yet another alternative memory cell having a quaternary M-GaTeSb phase change material.

FIG. 5 is a schematic diagram of a memory array using memory cells having a quaternary M-GaTeSb phase change material.

FIG. 6 simplified block diagram of an integrated circuit including a memory array as described herein.

FIG. 7 is a plot of resistivity versus temperature for an memory cell having a quaternary M-GaTeSb phase change material, where M is silicon.

FIG. 8 is a plot of resistivity versus temperature for an memory cell having a quaternary M-GaTeSb phase change material, where M is germanium.

FIG. 9 is a plot of resistivity versus temperature for an memory cell having a quaternary M-GaTeSb phase change material, where M is nitrogen.

FIG. 10 is a plot showing differential thermal analysis of a quaternary M-GaTeSb phase change material, where M is silicon.

FIG. 11 is a plot of x-ray diffraction analysis of a quaternary M-GaTeSb phase change material, where M is silicon.

FIG. 12 is a plot of crystalline phase resistivity versus concentration of M, and of the ratio of amorphous phase resistivity to crystalline phase resistivity versus concentration of M, where M is silicon.

FIG. 13 is a plot of crystalline phase resistivity versus concentration of M, and of the ratio of amorphous phase resistivity to crystalline phase resistivity versus concentration of M, where M is germanium.

FIG. 14 is a plot of crystalline phase resistivity versus concentration of M, and of the ratio of amorphous phase resistivity to crystalline phase resistivity versus concentration of M, where M is nitrogen.

FIGS. 15A and 15B are plots of undoped Ga₂Sb₂Te₅ device switching I-V: the SET current is about 2 mA; the RESET current is about 3 mA.

FIG. 16 is a plot of Si—GaTeSb device switching I-V.

FIG. 17 is a plot of Si—GaTeSb device switching I-V.

### DETAILED DESCRIPTION

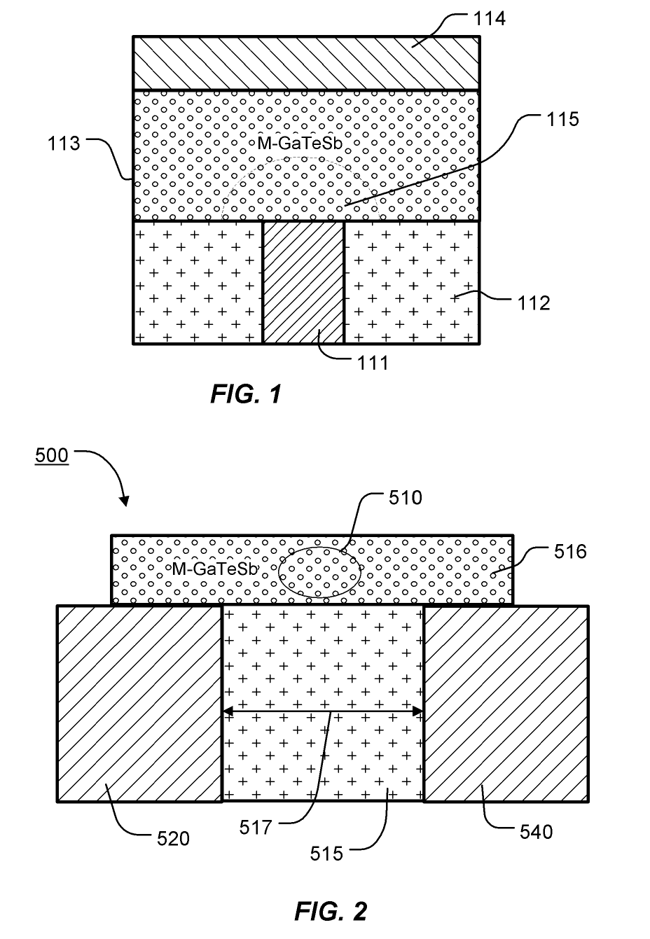

A detailed description of embodiments of the present invention is provided with reference to the FIGS. 1-17.

FIG. 1 illustrates a “mushroom type” memory cell having a first electrode 111 extending through dielectric 112, a memory element 113 comprising a body of phase change material comprising a quaternary M-GaTeSb phase change material, and a second electrode 114 on the memory element 113. The first electrode 111 is coupled to a terminal of an access device (not shown) such as a diode or transistor, while the second electrode 114 is coupled to a bit line and can be part of the bit line (not shown). The first electrode 111 has a width less than the width of the second electrode 114 and memory element 113, establishing a small contact area between the body of phase change material and the first electrode 111 and a relatively larger contact area between the body of phase change material and the second electrode 114, so that higher current densities are achieved with small absolute current values through the memory element 113. Because of this smaller contact area at the first electrode 111, the current density is largest in operation in the region adjacent the first electrode 111, resulting in the active region 115 having a “mushroom” shape as shown in the Figure.

The phase change material consists essentially of a quaternary system based on M-GaTeSb, having the formula:

M_{A}(GaₓTe_{y}Sb_{z})_{B}

Where M=IVA elements (C, Si, Ge, Sn, Pb), M=VA elements (N, P, As, Sb, Bi) or M=VIA elements (O, S, Se, Te, Po); and wherein x, y, z are selected to form a growth dominated crystallization system. Preferably, the variables (x, y, z) satisfy at least one of the relations (z>x and z>y) and (z≧x+y). Combinations x, y, z that likely result in a growth dominated system can include:
x, y, z=2, 1, 7
x, y, z=3, 2, 12
x, y, z=2, 3, 5
x, y, z=3, 1, 8
x, y, z=3, 2, 12

The first and second electrodes 111, 114 may comprise, for example, TiN or

TaN. Alternatively, the first and second electrodes 111, 114 may each be W, WN, TiAlN or TaAlN, or comprise, for further examples, one or more elements selected from the group consisting of doped-Si, Si, C, Ge, Cr, Ti, W, Mo, Al, Ta, Cu, Pt, Ir, La, Ni, N, O, and Ru and combinations thereof. In an example embodiment, the first electrode 111 comprises tungsten and the second electrode 114 comprises TaN.

A manufacturing process for manufacturing a memory cell includes formation of underlying access structures, not shown in FIG. 1. The underlying access circuitry can be formed by standard processes as known in the art, and the configuration of elements of the access circuitry depends upon the array configuration in which the memory cells described herein are implemented. Although there is a variety of architectures, in one common architecture, the access circuitry may include access devices such as FET or bipolar transistors and diodes, word lines and sources lines, conductive plugs, and doped regions within a semiconductor substrate, while bit lines overly the array.

The first electrode 111 having a contact surface is formed, extending through dielectric 112, using for example a tungsten plug process that includes deposition of the dielectric 112, followed by etching vias over corresponding access devices. Then the vias are filled with tungsten, and the upper surface of the resulting structure is planarized. In some embodiments the contact surface on top of the first electrode 111 has a sublithographic width or diameter.

Then a layer of quaternary M-GaTeSb is formed by co-sputtering over the planarized surface. Then the top electrode material, such as TaN, is deposited and patterned to form bit lines or other top electrode structures.

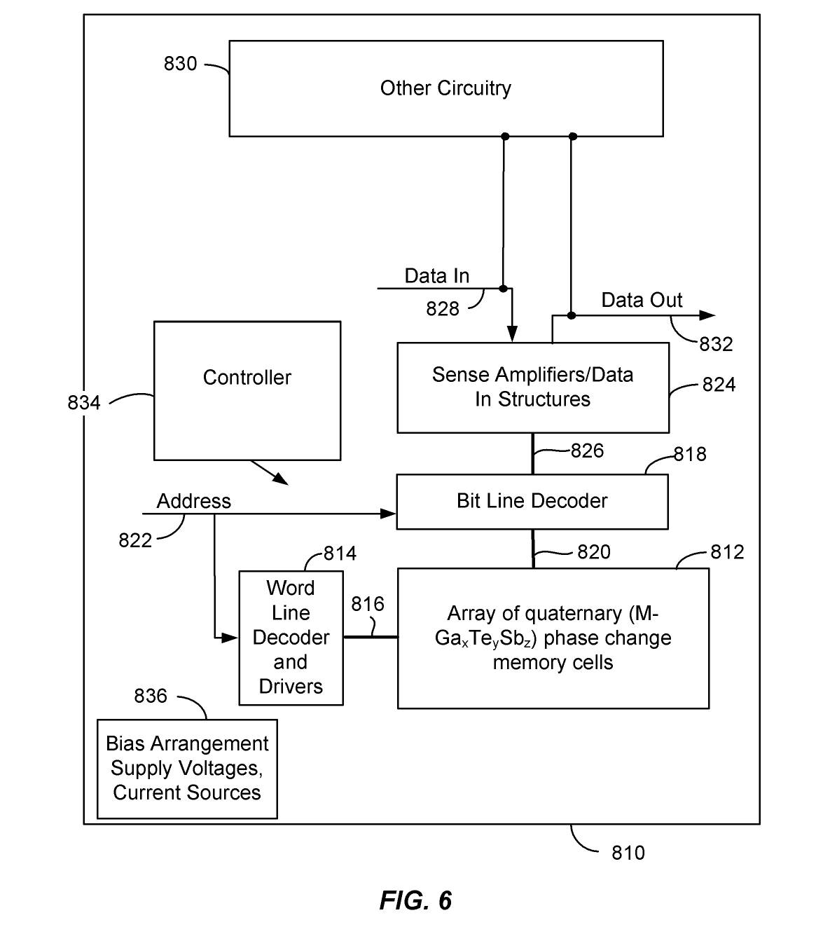

Next back-end-of-line (BEOL) processing is performed to complete the semiconductor process steps of the chip. The BEOL processes can be standard processes as known in the art, and the processes performed depend upon the configuration of the chip in which the memory cell is implemented. Generally, the structures formed by BEOL processes may include contacts, inter-layer dielectrics and various metal layers for interconnections on the chip including circuitry to couple the memory cell to peripheral circuitry. As a result of these processes, control circuits and biasing circuits as shown in FIG. 6 are formed on the device.

FIG. 2 illustrates a cross-sectional view of a second memory cell 500 having a quaternary M-GaTeSb phase change material forming a bridge type memory element 516, and having an active region 510 as described above.

The memory cell 500 includes a dielectric spacer 515 separating first and second electrodes 520, 540. The memory element 516 extends across the dielectric spacer 515 to contact the first and second electrodes 520, 540, thereby defining an inter-electrode current path between the first and second electrodes 520, 540 having a path length defined by the width 517 of the dielectric spacer 515. In operation, as current passes between the first and second electrodes 520, 540 and through the memory element 516, the active region 510 heats up more quickly than the remainder of the memory element 516.

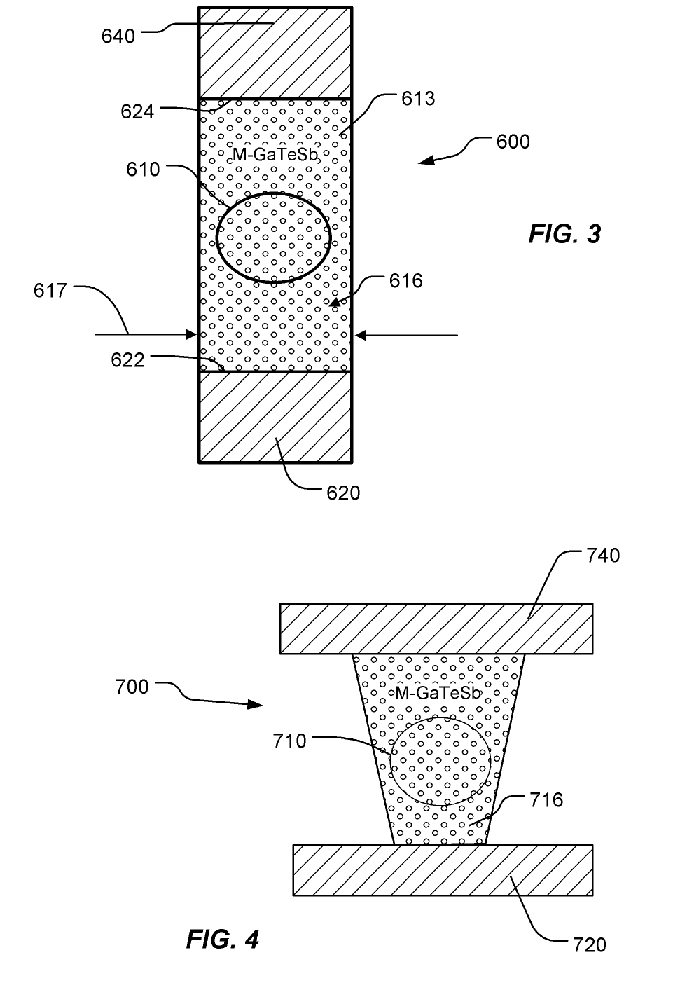

FIG. 3 illustrates a cross-sectional view of a third memory cell 600 having a quaternary M-GaTeSb phase change material forming a pillar-shaped memory element 616, and having an active region 610 as described above.

The memory cell 600 includes a pillar-shaped memory element 616 contacting first and second electrodes 620, 640 at top and bottom surfaces 622, 624, respectively. The memory element 616 has a width 617 substantially the same in this example, as that of the first and second electrodes 620, 640 to define a multi-layer pillar surrounded by dielectric (not shown). As used herein, the term “substantially” is intended to accommodate manufacturing tolerances. In operation, as current passes between the first and second electrodes 620, 640 and through the memory element 616, the active region 610 heats up more quickly than the remainder 613 of the memory element.

FIG. 4 illustrates a cross-sectional view of a fourth memory cell 700, a quaternary M-GaTeSb phase change material forming a pore-type memory element 716, and having an active region 710 as described above.

The memory cell 700 includes a pore-type memory element 716 surrounded by dielectric (not shown) contacting first and second electrodes 720, 740 at top and bottom surfaces, respectively. The memory element has a width less than that of the first and second electrodes, and in operation as current passes between the first and second electrodes and through the memory element the active region heats up more quickly than the remainder of the memory element.

As will be understood, the present invention is not limited to the memory cell structures described herein.

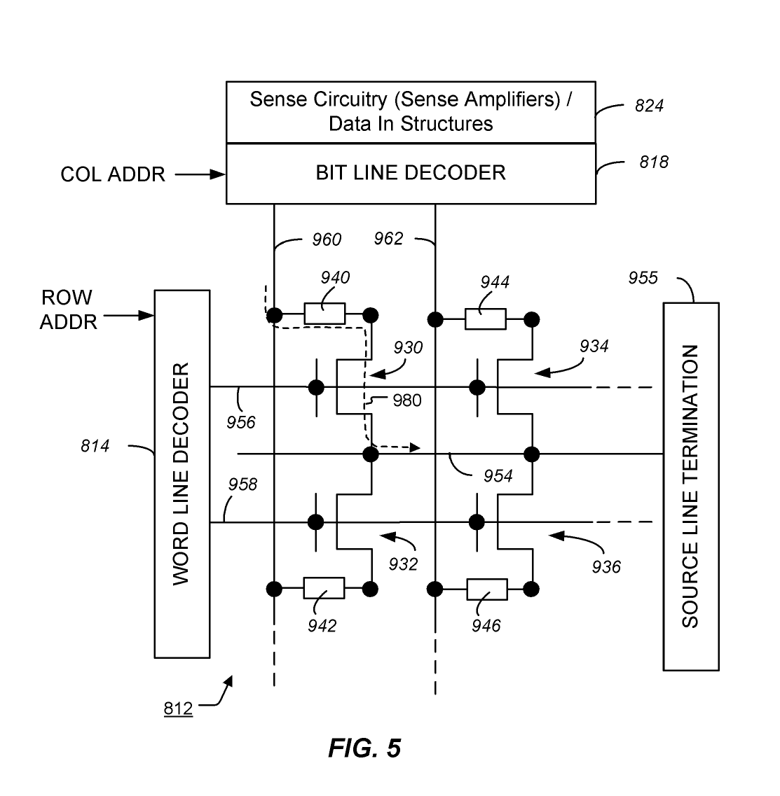

In FIG. 5, four memory cells 930, 932, 934, 936 having memory elements 940, 942, 944, 946 are illustrated, representing a small section of an array.

Sources of each of the access transistors of memory cells 930, 932, 934, 936 are connected in common to source line 954 that terminates in a source line termination circuit 955, such as a ground terminal. In another embodiment, the source lines of the access devices are not shared between adjacent cells, but are independently controllable. The source line termination circuit 955 may include bias circuitry such as voltage sources and current sources, and decoding circuits for applying bias arrangements, other than ground, to the source line 954, in some embodiments.

A plurality of word lines including word lines 956, 958 extend in parallel along a first direction. Word lines 956, 958 are in electrical communication with word line decoder 814. The gates of access transistors of memory cells 930 and 934 are connected to word line 956, and the gates of access transistors of memory cells 932 and 936 are connected in common to word line 958.

A plurality of bit lines including bit lines 960, 962 extend in parallel in a second direction and are in electrical communication with bit line decoder 818. In the illustrated embodiment, each of the memory elements are arranged between the drain of the corresponding access device and the corresponding bit line. Alternatively, the memory elements may be on the source side of the corresponding access device.

FIG. 6 is a simplified block diagram of an integrated circuit 810 including a memory array 812 implemented using memory cells based on a quaternary M-GaTeSb material as described herein. A word line decoder 814 having read, set and reset modes is coupled to and in electrical communication with a plurality of word lines 816 arranged along rows in the memory array 812. A bit line (column) decoder 818 is in electrical communication with a plurality of bit lines 820 arranged along columns in the array 812 for reading, setting, and resetting the phase change memory cells (not shown) in array 812. Addresses are supplied on bus 822 to word line decoder and drivers 814 and bit line decoder 818. Sense circuitry (Sense amplifiers) and data-in structures in block 824, including voltage and/or current sources for the read, set, and reset modes are coupled to bit line decoder 818 via data bus 826. Data is supplied via a data-in line 828 from input/output ports on integrated circuit 810, or from other data sources internal or external to integrated circuit 810, to data-in structures in block 824. Other circuitry 830 may be included on integrated circuit 810, such as a general purpose processor or special purpose application circuitry, or a combination of modules providing system-on-a-chip functionality supported by array 812. Data is supplied via a data-out line 832 from the sense amplifiers in block 824 to input/output ports on integrated circuit 810, or to other data destinations internal or external to integrated circuit 810.

A controller 834 implemented in this example, using a bias arrangement state machine, controls the bias circuitry voltage and current sources 836 for the application of bias arrangements including read, program, erase, erase verify and program verify voltages and/or currents for the word lines and bit lines. Controller 834 may be implemented using special-purpose logic circuitry as known in the art. In alternative embodiments, controller 834 comprises a general-purpose processor, which may be implemented on the same integrated circuit to execute a computer program to control the operations of the device. In yet other embodiments, a combination of special-purpose logic circuitry and a general-purpose processor may be utilized for implementation of controller 834.

The bias circuitry voltage and current sources in block 836 can be implemented using power supply inputs with voltage dividers and charge pumps, current source circuitry, pulse shaping circuitry, timing circuitry and voltage and current switches as are standard in the art.

In operation, each of the memory cells in the array 812 stores data depending upon the resistance of the corresponding memory element. The data value may be determined, for example, by comparison of current on a bit line for a selected memory cell to that of a suitable reference current by sense amplifiers of sense circuitry (block 824). The reference current can be established so that a predetermined range of currents correspond to a logical “0”, and a differing range of current corresponds to a logical “1”.

Reading or writing to a memory cell of array 812, therefore, can be achieved by applying a suitable voltage to one of word lines and coupling one of bit lines to a voltage source so that current flows through the selected memory cell. In FIG. 17 an example is shown in which a current path 980 through a selected memory cell (in this example memory cell 930 and corresponding memory element 940) is established by applying voltages to the bit line 960, word line 956, and source line 954 sufficient to turn on the access transistor of memory cell 930 and induce current in path 980 to flow from the bit line 960 to the source line 954, or vice-versa. The level and duration of the voltages applied is dependent upon the operation performed, e.g. a reading operation or a writing operation.

In a reset (or erase) operation of the memory cell, word line decoder 814 facilitates providing a word line with a suitable voltage pulse to turn on the access transistor of the memory cell. Bit line decoder 818 facilitates supplying a voltage pulse to a bit line of suitable amplitude and duration to induce a current to flow though the memory element, the current raising the temperature of the active region of the memory element above the transition temperature of the phase change material and also above the melting temperature to place the phase change material of the active region in a liquid state. The current is then terminated, for example, by terminating the voltage pulses on the bit line and on the word line, resulting in a relatively quick quenching time as the active region cools to a high resistance generally amorphous phase in the phase change domains of the active region to establish a high resistance reset state in the memory cell. The reset operation can also comprise more than one pulse, for example, using a pair of pulses.

In a set (or program) operation of the selected memory cell, word line decoder 814 facilitates providing a word line with a suitable voltage pulse to turn on the access transistor of the memory cell. Bit line decoder 818 facilitates supplying a voltage pulse to a bit line of suitable amplitude and duration to induce a current to flow through the memory element, the current pulse sufficient to raise the temperature of the active region above the transition temperature and cause a transition in the phase change domains of the active region from the high resistance generally amorphous condition into a low resistance generally crystalline condition, this transition lowering the resistance of all of the memory element and setting the memory cell to the low resistance state.

In a read (or sense) operation of the data value stored in the memory cell, word line decoder 814 facilitates providing a word line with a suitable voltage pulse to turn on the access transistor of the memory cell. Bit line decoder 818 facilitates supplying a voltage to a bit line of suitable amplitude and duration to induce current to flow through the memory element that does not result in the memory element undergoing a change in resistive state. The current on the bit line and through the memory cell is dependent upon the resistance of, and therefore the data state associated with, the memory cell. Thus, the data state of the memory cell may be determined by detecting whether the resistance of the memory cell corresponds to the high resistance state or the low resistance state, for example by comparison of the current on the corresponding bit line with a suitable reference current by sense amplifiers of sense circuitry (block 824).

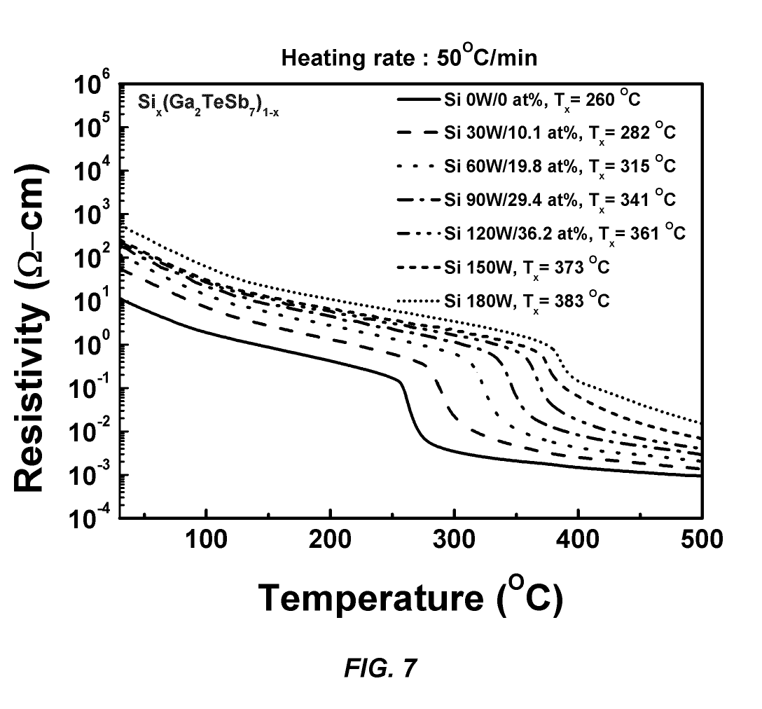

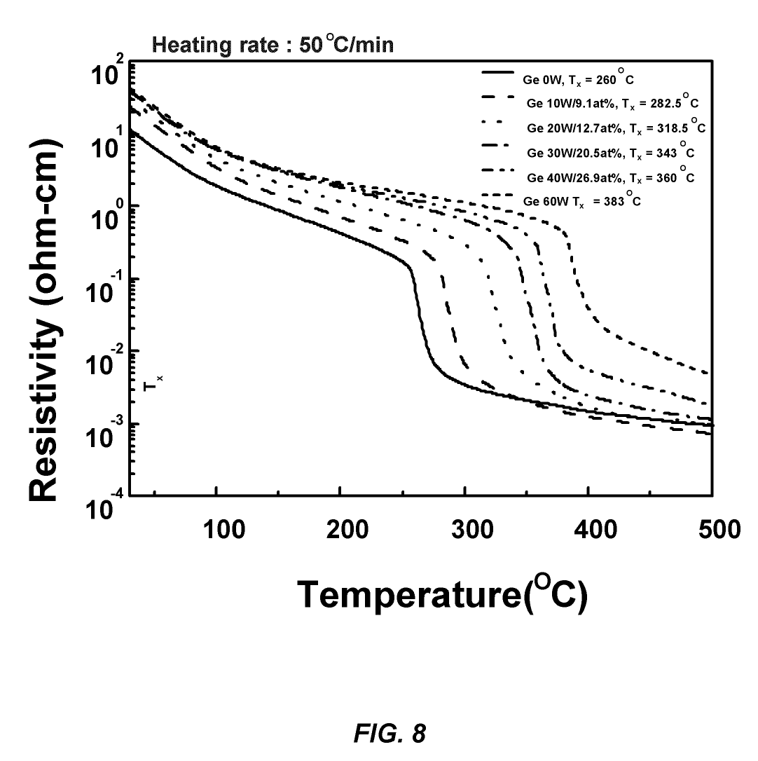

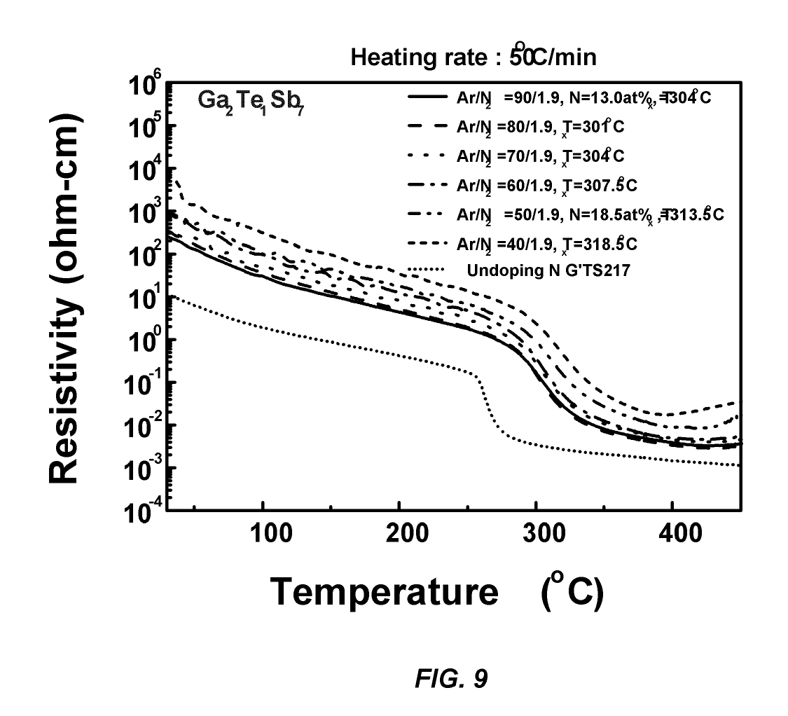

FIGS. 7-9 are graphs of resistivity versus temperature for M-GaTeSb phase change material, where M is silicon in various concentrations in FIG. 7, M is germanium in various concentrations in FIG. 8 and M is nitrogen in various concentrations in FIG. 9. As shown, by adding a fourth element into the GaTeSb material, crystallization temperatures are increased significantly. Crystallization temperatures are indicated by the sharp drops in resistivity.

In FIG. 7, results where M is silicon are shown, where the silicon concentration was modified by increasing the power on the silicon co-sputter target. For power levels of 30, 60, 90 and 120 Watts, the silicon concentration was measured. The measurements show 10.1, 19.8, 29.4 and 36.2 at % silicon, respectively. For powers of 150 and 180 Watts, the silicon concentrations were not directly measured. Measured compositions are shown in the following table.

| | |
|---|---|
| RF power (W) | Atomic % |

| Ga₂TeSb₇ | Si | Ga | Te | Sb | Si |
|---|---|---|---|---|---|
| 50 | 30 | 14.6 | 9.2 | 66.1 | 10.1 |
| 50 | 60 | 14.7 | 8.1 | 57.3 | 19.8 |
| 50 | 90 | 13.2 | 7.3 | 50.1 | 29.4 |
| 50 | 120 | 12.0 | 6.4 | 45.4 | 36.2 |

In FIG. 8, results where M is germanium are shown, where the germanium concentration was modified by increasing the power on the germanium co-sputter target. For power levels of 10, 20, 30 and 40 Watts, the silicon concentration was measured. The measurements show 9.1, 12.7, 20.5 and 26.9 at % germanium, respectively. For a power of 50 Watts, the germanium concentration was not directly measured. Measured compositions are shown in the following table.

| | |
|---|---|
| RF power (W) | Atomic % |

| Ga₂TeSb₇ | Ge | Ga | Te | Sb | Ge |
|---|---|---|---|---|---|
| 50 | 10 | 16.3 | 9.6 | 65 | 9.1 |
| 50 | 20 | 9.5 | 10.5 | 67.3 | 12.7 |
| 50 | 30 | 9.1 | 9.3 | 61.1 | 20.5 |
| 50 | 40 | 8.4 | 9.5 | 56.2 | 26.9 |

In FIG. 9, results where M is nitrogen are shown, where the nitrogen concentration was modified by increasing relative gas flow rate of the argon to nitrogen carrier (in this case by reducing the argon flow rate) in the sputter chamber. Results for argon to nitrogen flow rate ratios of 90/1.9, 80/1.9, 70/1.9, 60/1.9, 50/1.9 and 40/1.9 are plotted Measured compositions are shown in the following table.

| | |
|---|---|
| RF power (W) | Atomic % |

| Ga₂TeSb₇ | Ar/N2 | Ga | Te | Sb | N |
|---|---|---|---|---|---|
| 50 | 90/1.9 | 14.1 | 8.4 | 64.5 | 13.0 |
| 50 | 50/1.9 | 13.6 | 7.9 | 59.9 | 18.5 |

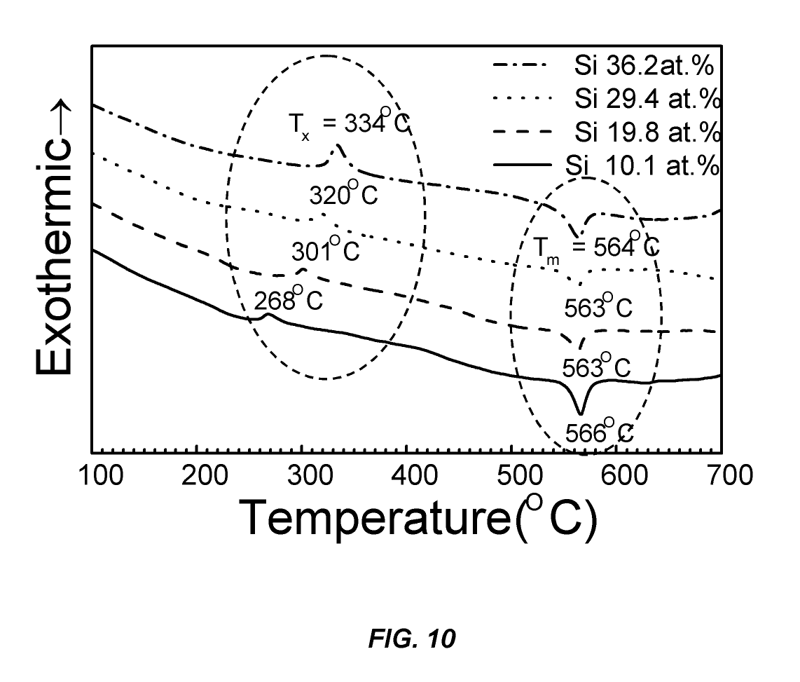

FIG. 10 is a graph of differential thermal analysis of Si—GaTeSb, plotting exothermic changes in the sample relative to a reference. The analysis shows relatively: high crystallization temperatures (Tx), and relatively low melting temperatures (Tm) for the samples. As concentration of the fourth element (silicon in this example) increases, a significant increase in crystallization temperature (Tx) is observed, while the melting temperature stays roughly the same. This results in a reduction in the difference between the melting temperature and the crystallization temperature (Tm-Tx falls from 298 to 262 to 243 to 230, for the four samples as the concentration of the fourth element increases, without substantial increases in the melting temperature. As a result, the reset power does not increase, or may actually fall, with increasing concentrations for the fourth element. Thereby power required in operation of the devices is reduced or maintained while improving device performance.

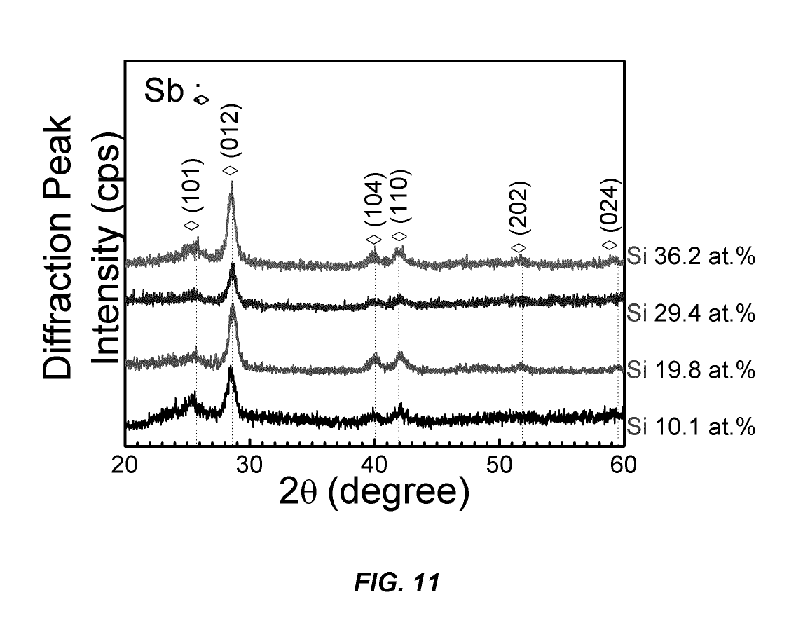

FIG. 11 is a plot of 20 from X-ray diffraction analysis. As shown, X-ray diffraction shows no differences in 2q for various Si-compositions. This suggests that the crystalline structure is not distorted significantly by the addition of increased amounts of the fourth element.

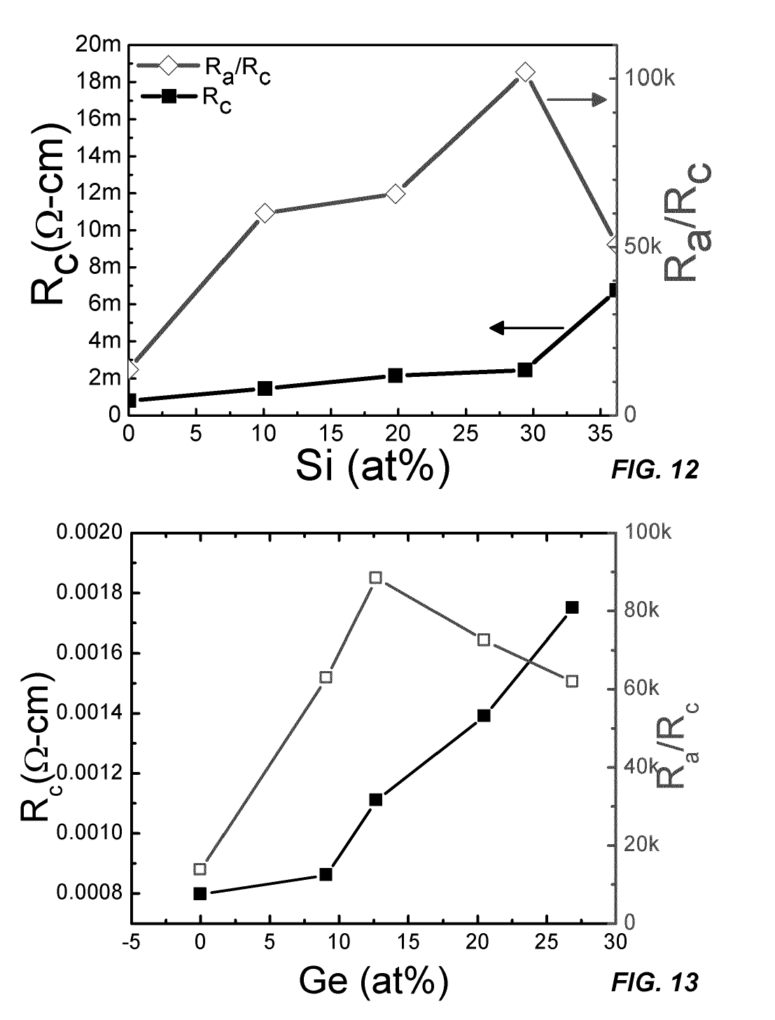

FIGS. 12-14 are plots of crystalline phase resistivity versus concentration of M, and the ratio of amorphous phase resistivity to crystalline phase resistivity versus concentration of M. The fourth element M is silicon, germanium, and nitrogen, respectively, in the figures. These plots illustrate that by selecting a suitable thin film crystalline phase resistance along with a suitable ratio of amorphous phase resistivity to crystalline phase resistivity, a memory device can be provided with good performance characteristics.

FIG. 12 illustrates that for the M-GaTeSb, where M is silicon, excellent characteristics are shown at a silicon concentration of about 29 at %. Above about 30 at % silicon the crystalline phase resistivity increases rapidly, and the ratio falls rapidly. Suitable device characteristics are seen in a range from about 10 at % to about 30 at %.

FIG. 13 illustrates that for the M-GaTeSb where M is germanium, excellent characteristics are shown at a germanium concentration of about 13 at %. Above about 13 at % silicon the crystalline phase resistivity increases rapidly, and the ratio falls rapidly. Suitable device characteristics are seen in a range from about 8 at % to about 15 at %.

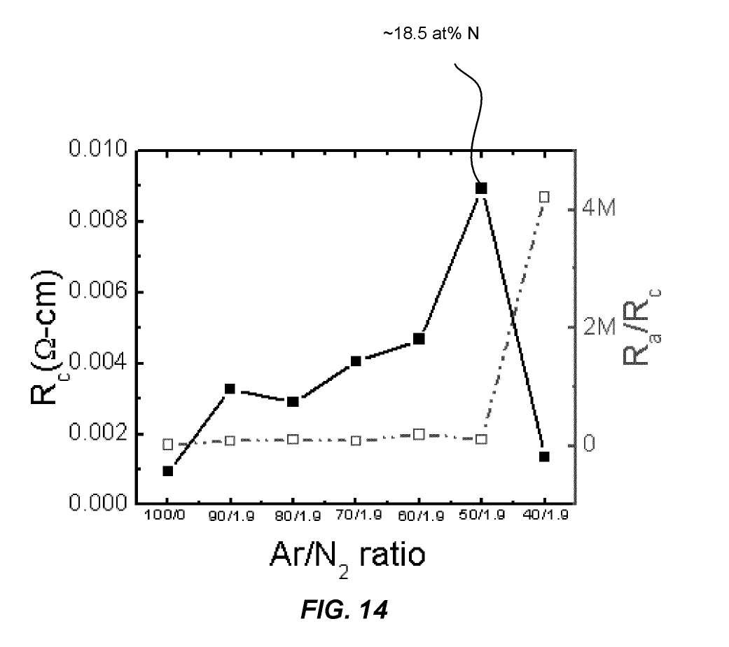

FIG. 14 illustrates that for the M-GaTeSb where M is nitrogen, excellent characteristics are shown at a nitrogen concentration of about 18.5 at %. Above about 18.5 at % nitrogen the crystalline phase resistivity increases rapidly, and the ratio falls rapidly. Suitable device characteristics are seen in a range from about 13 at % to about 19 at %.

Bake testing at 250° C. for more than 1680 seconds, of a memory device having a structure like that of FIG. 1, with a bottom electrode diameter of about 0.18 microns, and a memory material of M-GaTeSb, where M is silicon, at concentration of about 29 at %, shows good retention characteristics. Also, cycle testing of the same device yields reliable operation for the tested device for over one million cycles, suggesting even higher reliability in a production device.

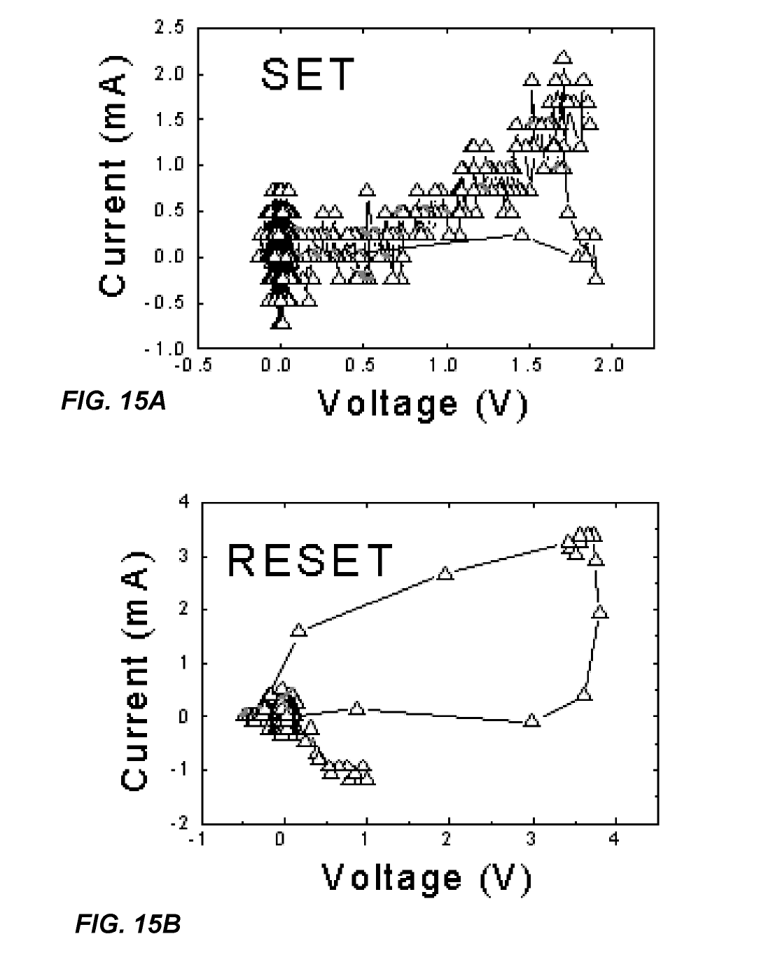

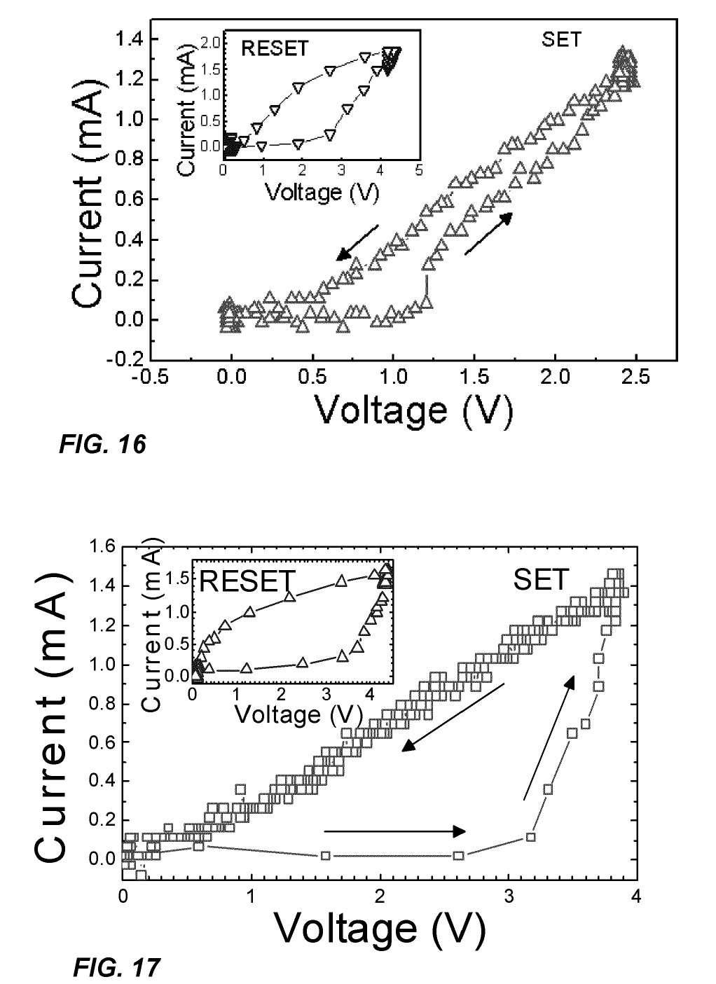

FIG. 16 illustrates that current versus voltage plots for the tested Si—GaTeSb device switching show a set current of about 1 milliAmp, and a reset current less than 2 milliAmp, as compared to FIGS. 15A and 15B show set and reset IV characteristics of an undoped Ga₂Sb₂Te₅ device where the set current would be about 2 milliAmp and the reset current about 3 milliAmp. Example operation set pulses include a sequence of pulses: (1) from 0 to 2.5 Volts with durations of 200 nanoseconds; (2) applying 2.5 Volts for 20 microseconds; and (3) from 2.5 to 0 Volts with durations of 200 nanoseconds. A reset pulse of 4.5 Volts for 10 nanoseconds and followed by a fast quench can be used for example.

FIG. 17 further illustrates the tested Si—GaTeSb device has better I-V characteristics, which shows a set current of about 1.4 milliAmp, and a reset current of about 1.5 milliAmp, where the operation set pulses include a sequence of pulses: (1) from 0 to 3.9 Volts (2) applying 3.9 Volts with durations of 10 nanoseconds; and (3) from 3.9 to 0 Volts with durations of 100 nanoseconds. A reset pulses of 4.3 Volts for 10 nanoseconds and followed by a fast quench can be used for example. Under such operation pulses, the tested Si—GaTeSb device demonstrates similar SET current, but setting period is much shorter. The fast RESET at a relatively low voltage is a result of the high crystalline resistance and low melting temperature of the material.

The fast RESET action at a relatively low voltage is a result of the high crystalline resistance and low melting temperature of the material. The long SET pulse needed to crystallize the phase change material is consistent with the intrinsic high crystallization temperature of the M-GaTeSb family. The high crystallization temperature of Si_{29.4}(Ga₂TeSb₇)_{70.6} suggests excellent retention and high temperature performances.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A phase change material having a melting temperature and a crystallization transition temperature, and a difference between the melting temperature and transition temperature, comprising:
quaternary M_{A}(GaₓTe_{y}Sb_{z})_{B}, where x, y and z are variables, where M comprises an element, and wherein A and B are positive, non-zero numbers, wherein the combination of variables (x,y,z) satisfy the at least one of the following: (z>x and z>v) and (z≧x+y).

2. The phase change material of claim 1, wherein the combination of variables (x,y,z) is selected from (2, 1, 7), (3, 2, 12), (2, 3, 5), (3, 1, 8), or (3, 2, 12).

3. The phase change material of claim 1, having a value A such that the transition temperature is increased relative to the transition temperature in GaₓTeₓSb_{z}, without M, and the difference between the melting temperature and the transition temperature is reduced relative to the difference in GaₓTeₓSb_{z}, without M.

4. The phase change material of claim 1, wherein M comprises silicon.

5. The phase change material of claim 1, wherein M comprises germanium.

6. The phase change material of claim 1, wherein M comprises nitrogen.

7. The phase change material of claim 1, wherein M comprises silicon with a concentration of between 10 and 30 at %.

8. The phase change material of claim 1, wherein M comprises germanium with a concentration of between 8 and 23 at %.

9. The phase change material of claim 1, wherein M comprises nitrogen with a concentration of between 13 and 19 at %.

10. A memory device comprising a first electrode, a memory element and a second electrode, wherein the memory element comprises a phase change material having a melting temperature and a crystallization transition temperature, and a difference between the melting temperature and transition temperature, comprising:
a growth dominated crystallization quaternary GaₓTe_{y}Sb_{z} material M_{A}(GaₓTe_{y}Sb_{z})_{B}), where M comprises an element and wherein A and B are positive, non-zero numbers, wherein the combination of variables (x,y,z) satisfy the at least one of the following: (z>x and z>y) and (z≧x+y).

11. The memory device of claim 10, wherein M comprises silicon.

12. The memory device of claim 10, wherein M comprises germanium.

13. The memory device of claim 10, wherein M comprises nitrogen.

14. The memory device of claim 10, wherein M comprises silicon with a concentration of between 10 and 30 at %.

15. The memory device of claim 10, wherein M comprises germanium with a concentration of between 8 and 23 at %.

16. The memory device of claim 10, wherein M comprises nitrogen with a concentration of between 13 and 19 at %.

17. The memory device of claim 10, wherein M comprises an element select from C, Si, Ge, Sn, Pb, N, P, As, Sb, Bi, O, S, Se, Te, and Po, and wherein A and B are positive, non-zero numbers, having a value A such that the transition temperature is increased relative to the transition temperature in GaₓTe_{y}Sb_{z}, without M, and the difference between the melting temperature and the transition temperature is reduced relative to the difference in GaₓTe_{y}Sb_{z}, without M, and further characterized by being a growth dominated crystallization system.

18. A phase change material having a melting temperature and a crystallization transition temperature, and a difference between the melting temperature and transition temperature, comprising:
quaternary M_{A}(GaₓTe_{y}Sb_{z})_{B}, where x, y and z are variables, wherein the combination of variables (x,y,z) satisfy the at least one of the following: (z>x and z>y) and (z≧x+y);
where M comprises an element selected from C, Si, Ge, Sn, Pb, N, P, As, Sb, Bi, O, S, Se, Te, and Po, and wherein A and B are positive, non-zero numbers, having a value A such that the transition temperature is increased relative to the transition temperature in GaₓTe_{y}Sb_{z}, without M, and the difference between the melting temperature and the transition temperature is reduced relative to the difference in GaₓTe_{y}Sb_{z}, without M.

19. A phase change material having a melting temperature and a crystallization transition temperature, and a difference between the melting temperature and transition temperature, comprising:
M_{A}(Ga₂TeSb₇)_{B}, where x, y and z are variables, where M is Si and wherein A and B are positive, non-zero numbers, so that the Si concentration is in the range of 20 at % to 30 at %, inclusive.

20. A phase change material having a melting temperature and a crystallization transition temperature, and a difference between the melting temperature and transition temperature, comprising:
M_{A}(Ga₂TeSb₇)_{B}, where x, y and z are variables, where M is Ge and wherein A and B are positive, non-zero numbers, so that the Ge concentration is in the range of 5 at % to 15 at %, inclusive.
